(19) United States
(12) Patent Application Publication
(10) Pub. No.: US 2026/0065822 A1
(43) Pub. Date: Mar. 5, 2026

(54) LIGHT EMITTING DISPLAY DEVICE

(71) Applicant: LG Display Co., Ltd., Seoul (KR)

(72) Inventor: Jun-Hee HAN, Paju-si (KR)

(73) Assignee: LG Display Co., Ltd., Seoul (KR)

(21) Appl. No.: 19/285,716

(22) Filed: Jul. 30, 2025

(30) Foreign Application Priority Data
Sep. 2, 2024 (KR) 10-2024-0118395

(51) Int. Cl. G09G 3/00; G09G 3/3233

(52) U.S. Cl. CPC G09G 3/006; G09G 3/3233; G09G 2300/0842; G09G 2320/0233; G09G 2330/10

(57) ABSTRACT

A light emitting display device includes a substrate having a display region in which subpixels are arranged along row lines and column lines, and a light emitting diode in the subpixel. The light emitting diode includes an anode electrode, a light emitting layer on the anode electrode, and a cathode electrode on the light emitting layer. The display device further includes a test transistor in the row line and including a source electrode connected to the anode electrode of one of neighboring subpixels in the row line and a drain electrode connected to the cathode electrode of the other of the neighboring subpixels in the row line, and a test gate line connected to a gate electrode of the test transistor. When the test transistor is turned on and a current path is formed in the row line, the cathode electrode is in an electrically floating state.

### CROSS-REFERENCE TO RELATED APPLICATIONS

The present application claims priority to Korean Patent Application No. 10-2024-0118395, filed in Republic of Korea on Sep. 2, 2024, which is hereby expressly incorporated by reference in its entirety for all purposes as if fully set forth herein into the present application.

### BACKGROUND

### Field of the Invention

The present invention relates to a light emitting display device.

### Discussion of the Related Art

Recently, flat panel display devices with excellent characteristics such as thinness, weight reduction, and low power consumption have been widely developed and applied to various fields.

Among the flat panel display devices, light emitting display devices equipped with light emitting elements such as light emitting diodes emit light when charges are injected into a light emitting layer formed between an anode electrode and a cathode electrode, and electrons and holes are paired and then extinguished.

When there is a defect in the light emitting display device, a dark spot can occur, and a main cause of such dark spot occurrence can be predicted to be a short circuit between the anode electrode and the cathode electrode, i.e., an AC short circuit. However, in reality, it can be difficult to confirm whether or not the dark spot defect is indeed caused by the AC short circuit. Accordingly, it can be difficult to address the dark spot defect issue.

### SUMMARY OF THE INVENTION

An advantage of the present invention is to provide a light emitting display device that can improve a detection rate of a dark spot defect caused by an AC short circuit.

Additional features and advantages of the invention will be set forth in the description which follows, and in part will be apparent from the description, or can be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, a light emitting display device includes: a substrate including a display region in which subpixels are arranged along row lines and column lines; a light emitting diode in the subpixel and including an anode electrode, a light emitting layer on the anode electrode, and a cathode electrode on the light emitting layer; a test transistor in the row line and including a source electrode connected to the anode electrode of one among neighboring subpixels in the row line and a drain electrode connected to the cathode electrode of the other one among the neighboring subpixels in the row line; and a test gate line connected to a gate electrode of the test transistor, wherein when the test transistor is turned on and a current path is formed in the row line, the cathode electrode is in an electrically floating state.

In another aspect of the present invention, a light emitting display device includes: a substrate including a display region in which subpixels are arranged along row lines and column lines; a light emitting diode in the subpixel; and a test transistor in the row line and connected between an anode electrode of the light emitting diode of one among neighboring subpixels in the row line and a cathode electrode of the light emitting diode of the other among the neighboring subpixels in the row line, wherein when the test transistor is turned on and the light emitting diodes of the row line are electrically connected in series, the cathode electrode is in an electrically floating state.

It is to be understood that both the foregoing general description and the following detailed description are examples and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a view schematically illustrating a light emitting display device according to an embodiment of the present invention;

FIG. 2 is a view schematically illustrating a circuit structure of a subpixel of a light emitting display device according to an embodiment of the present invention;

FIG. 3 is a view illustrating a driving in a test process of a light emitting display device according to an embodiment of the present invention;

FIG. 4 is a view illustrating a light emitting state in a test process when a dark spot defect due to an AC short circuit exists in a light emitting display device according to an embodiment of the present invention;

FIG. 5 is a view illustrating a light emitting state in a test process when a dark spot defect due to a defect other than an AC short circuit exists in a light emitting display device according to an embodiment of the present invention;

FIG. 6 is a plan view schematically illustrating a subpixel of a light emitting display device according to an embodiment of the present invention;

FIG. 7 is a cross-sectional view taken along a line VII-VII′ of FIG. 6; and

FIG. 8 is a cross-sectional view taken along a line VIII-VIII′ of FIG. 6.

### DETAILED DESCRIPTION OF THE EMBODIMENTS

Advantages and features of the present invention and methods of achieving them will be apparent with reference to the embodiments described below in detail with the accompanying drawings. However, the present invention is not limited to the embodiments disclosed below, but can be realized in a variety of different forms, and only these embodiments allow the present invention to be complete. The present invention is provided to fully inform the scope of the invention to the skilled in the art of the present invention, and the present invention can be defined by the scope of the claims.

The shapes, sizes, proportions, angles, numbers, and the like disclosed in the drawings for explaining the embodiments of the present invention are illustrative, and the present invention is not limited to the illustrated matters. The same reference numerals refer to the same components throughout the description.

Furthermore, in describing the present invention, if it is determined that a detailed description of the related known technology unnecessarily obscure the subject matter of the present invention, the detailed description thereof can be omitted. When ‘comprising’, ‘including’, ‘having’, ‘consisting’, and the like are used in this invention, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

In the case of a description of a temporal relationship, for example, when a temporal precedence is described as ‘after’, ‘following’, ‘before’, and the like, cases that are not continuous can be included unless ‘directly’ or ‘immediately’ is used.

In describing components of the present invention, terms such as first, second and the like can be used. These terms are only for distinguishing the components from other components, and an essence, order, order, or number of the components is not limited by the terms. Further, the term “can” fully encompasses all the meanings and coverages of the term “may” and vice versa.

Respective features of various embodiments of the present invention can be partially or wholly connected to or combined with each other and can be technically interlocked and driven variously, and respective embodiments can be independently implemented from each other or can be implemented together with a related relationship.

Hereinafter, embodiments of the present invention are described in detail with reference to the drawings. All the components of each light emitting display device/apparatus according to all embodiments of the present disclosure are operatively coupled and configured. Meanwhile, in the following embodiments, the same and like reference numerals are assigned to the same and like components, and detailed descriptions thereof can be omitted.

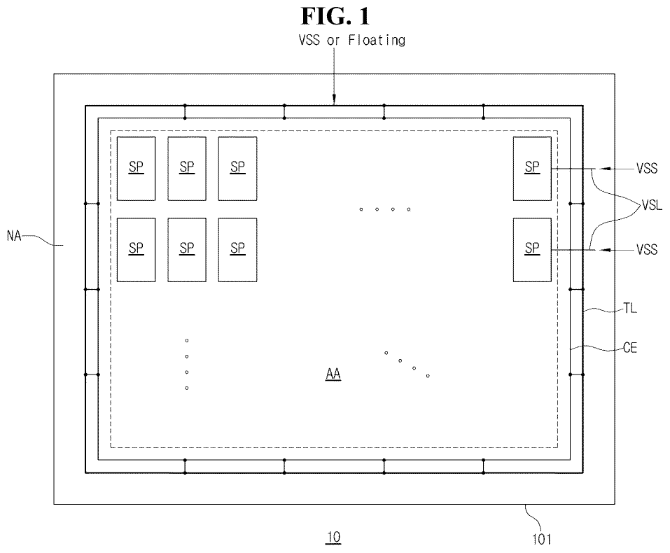

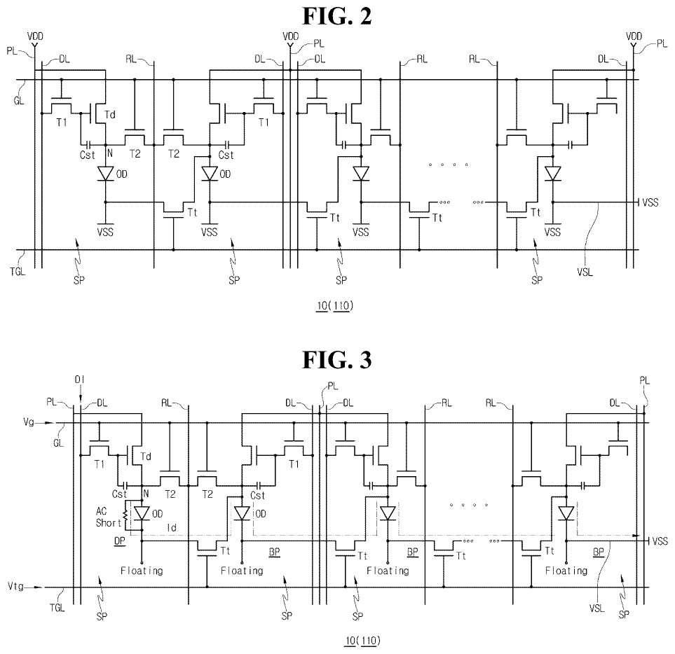

FIG. 1 is a view schematically illustrating a light emitting display device according to an embodiment of the present invention. FIG. 2 is a view schematically illustrating a circuit structure of a subpixel of a light emitting display device according to an embodiment of the present invention.

Prior to a specific description, the light emitting display device 10 according to the embodiments of the present invention can include all types of display devices that include light emitting diodes OD, which are self-luminous elements, to display images.

In the embodiments, for convenience of explanations, an organic light emitting display device is used as an example of the light emitting display device 10.

Referring to FIGS. 1 and 2, in the light emitting display device 10 (or its light emitting display panel) of the present embodiment, a display region AA (or active area) for displaying an image and a non-display region NA (or non-active area) arranged around the display region AA can be defined.

In the display region AA, a plurality of subpixels SP arranged along a plurality of row lines (or horizontal lines) and a plurality of column lines (or vertical lines) can be formed on a substrate 101.

In addition, on the substrate 101, a plurality of gate lines GL extending along the row direction (or horizontal direction or first direction) and a plurality of data lines DL extending along the column direction (or vertical direction or second direction) can be formed. In addition, on the substrate 101, a power line PL that transmits a high potential voltage (or first driving voltage) VDD to the subpixel SP can be formed, and a reference line RL that transmits a sensing voltage for compensation of characteristics of a driving transistor Td, for example, threshold voltage and/or mobility compensation, and also provides a reference voltage to the subpixel SP can be formed.

Furthermore, in this embodiment, a plurality of test gate lines TGL extending along the row direction can be formed on the substrate 101. For example, the test gate lines TGL can extend in parallel with the gate line GL in each row line.

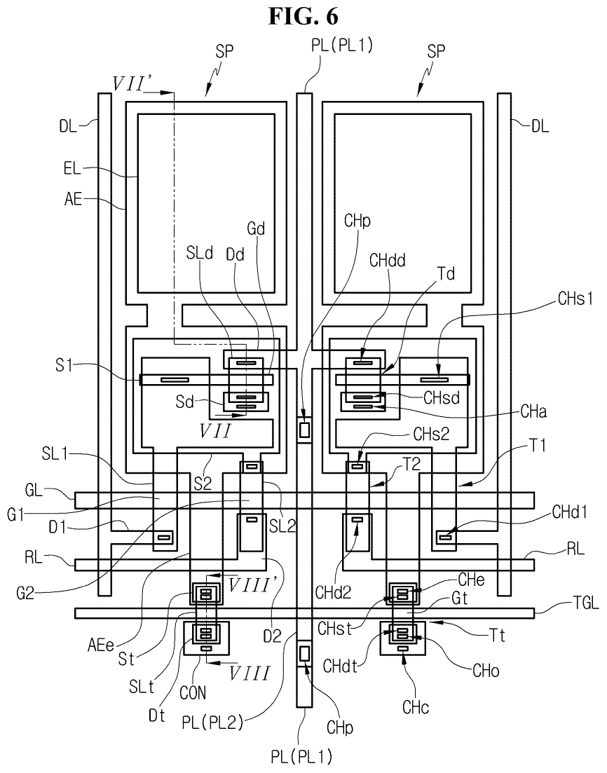

As described below, the test gate line TGL can be driven in a test process for detecting a dark spot defect due to a short circuit between the anode electrode (AE of FIG. 6) and the cathode electrode CE, i.e., an AC short circuit, within the subpixel SP.

During a normal operation for displaying an image, the plurality of gate lines GL can be sequentially scanned in a unit of a row line and be applied with respective gate signals.

Meanwhile, in the test process for detecting the dark spot defect, the plurality of test gate lines TGL can be sequentially scanned in a unit of a row line and be applied with respective test gate signals. In addition, in the test process, a sequential scan operation can be performed for the plurality of gate lines GL.

The plurality of subpixels SP can include subpixels SP of different colors that constitute a pixel which is a unit for displaying a color image. In this regard, the plurality of subpixels SP can include subpixels SP that respectively display first, second, and third colors, for example, red, green, and blue subpixels SP, but not limited thereto.

Each subpixel SP can include the light emitting diode OD, and a plurality of transistors and at least one capacitor for driving the light emitting diode OD.

Meanwhile, in this embodiment, for convenience of explanations, a 3TIC structure in which the subpixel SP is provided with three transistors T1, T2 and Td and one capacitor Cst, as illustrated in FIG. 2, is taken as an example.

The subpixel SP can be described with reference to FIG. 2. Meanwhile, for convenience of explanations, FIG. 2 illustrates the subpixels SP arranged along one row line (or a n-th row line). In addition, the case where two neighboring subpixels SP in a row line are commonly connected to the reference line RL arranged between them is illustrated as an example. In addition, the case where two neighboring subpixels SP in a row line are commonly connected to the power line PL arranged between them is illustrated as an example.

In addition, in the description below, terms, source electrode and drain electrode of a transistor are used to distinguish two electrodes connected to a semiconductor layer, and the terms can be used interchangeably in some cases.

The subpixel SP can include a first transistor T1 and a second transistor T2, which are switching transistors, a driving transistor Td, a storage capacitor Cst, and a light emitting diode OD. The first transistor T1 can be a data supply transistor, and the second transistor T2 can be a sensing transistor.

The first and second transistors T1 and T2, the driving transistor Td, and the storage capacitor Cst can constitute a pixel driving circuit for driving the light emitting diode OD in an image display operation. In other words, the first and second transistors T1 and T2, the driving transistor Td, and the storage capacitor Cst can form a pixel driving circuit for performing normal driving for displaying an image through the light emitting display device 10.

Furthermore, in this embodiment, a test transistor Tt, which is a switching transistor connected between adjacent subpixels SP in a row line, can be formed.

The test transistor Tt can be operated and used in a test process for detecting a dark spot defect caused by an AC short circuit.

In addition, after the test process is performed, the test transistor Tt can be substantially turned off (or disabled) and may not operate.

The test transistor Tt can be placed, for example, in one of two adjacent subpixels SP. In this embodiment, for convenience of explanations, an example is given in which the test transistor Tt is placed in the right subpixel SP among the two subpixels SP connected to the test transistor Tt. In this case, as illustrated in FIG. 2, the test transistor Tt can be placed in each of the subpixels SP of the remaining column lines except for the first column line on the left within the row line.

As another example, the test transistor Tt can be placed in the left subpixel SP among the two subpixels SP connected thereto.

As the test transistor Tt is placed as above, the subpixels SP in each row line can be electrically connected in series through the test transistors Tt connected therebetween. More specifically, the light emitting diodes OD of the subpixels SP in the row line can be electrically connected in series through the test transistors Tt.

Accordingly, an electrical current path of the subpixels SP in the row line can be formed through the test transistors Tt, so that a dark spot defect caused by an AC short circuit can be effectively detected. This is described in more detail below.

Regarding an electrical connection relationship of components placed in the subpixel SP, the first transistor T1 can be connected to the corresponding gate line GL and data line DL. In this regard, a drain electrode (or source electrode) of the first transistor T1 can be connected to the data line DL, and a gate electrode of the first transistor T1 can be connected to the gate line GL.

The driving transistor Td can have a gate electrode connected to a source electrode of the first transistor T1, a drain electrode (or source electrode) connected to the power line PL to receive the high potential voltage VDD, and a source electrode (or drain electrode) connected to an anode electrode of the light emitting diode OD.

The second transistor T2 can be connected to the corresponding gate line GL and reference line RL. In this regard, a drain electrode (or source electrode) of the second transistor T2 can be connected to the reference line RL, a gate electrode of the second transistor T2 can be connected to the gate line GL, and a source electrode (or drain electrode) of the second transistor T2 can be connected to a node N between the driving transistor Td and the light emitting diode OD. In other words, the source electrode of the second transistor T2 can be connected to the source electrode of the driving transistor Td and the anode electrode of the light-emitting diode OD.

As such, in this embodiment, the case where the second transistor T2 and the first transistor T1 in the subpixel SP are connected to the same gate line GL and receive the same gate signal is taken as an example. As another example, the second transistor T2 can be configured to be connected to the gate line GL different from the gate line GL connected to the first transistor T1.

The cathode electrode CE of the light emitting diode OD can be applied with a low potential voltage (or second driving voltage) VSS. The low potential voltage VSS is a voltage of a lower potential than the high-potential voltage VDD and can include a ground voltage.

Meanwhile, referring to FIG. 1, the cathode electrode CE can be formed over the entire display region AA of the light emitting display device 10. In other words, the cathode electrode CE can be formed integrally corresponding to all subpixels SP within the display region AA.

Regarding the cathode electrode CE, when the light emitting display device 10 is normally operated, the low potential voltage VSS can be applied to display an image. In the test process, when the test transistor Tt is driven to detect a dark spot defect, the cathode electrode CE can have a floating state without actually being applied with the low potential voltage VSS in order to form a current path along the row line.

In this regard, for example, the cathode electrode CE can be connected to a transmission line TL arranged in the non-display region NA, and the transmission line TL can be formed in a form that surrounds the display region AA along a periphery of the display region AA. In this case, when the low potential voltage VSS is supplied from an external power circuit to the transmission line TL, the low potential voltage VSS can be applied to the cathode electrode CE through the transmission line TL, so that the low potential voltage VSS can be uniformly (or evenly) supplied to the subpixels SP within the display region AA.

Meanwhile, when an output of the low potential voltage VSS from the power circuit is turned off, the transmission line TL can become a floating state in which no voltage is applied, so that the cathode electrode CE within the display region AA can become a floating state. In other words, in this case, the cathode electrode CE of the light emitting diode OD of the subpixel SP within the display region AA can become a floating state.

The storage capacitor Cst can be connected between the gate electrode and the source electrode of the driving transistor Td.

In the case configured as above, in operating in a display mode for displaying an image, when the gate signal is applied through the gate line GL, the first transistor T1 can be turned on and a data signal can be input to the subpixel SP, and the data signal can be applied to the gate electrode of the driving transistor Td. At this time, the second transistor T2 can be turned on and a reference voltage can be applied to the source electrode of the driving transistor Td. Accordingly, the data signal and the reference voltage can be applied to both electrodes of the storage capacitor Cst, so that the data signal can be stored in the storage capacitor Cst.

Then, when the gate signal is not applied to the gate line GL and is in an off state, the first and second transistors T1 and T2 can be turned off, the driving transistor Td can be turned on, and an emission current (or driving current) corresponding to the applied data signal can flow to the light emitting diode OD through the driving transistor Td. Accordingly, light corresponding to the emission current can be generated and output from the light emitting diode OD.

Meanwhile, in operating in a compensation mode for compensating the driving transistor Td, a sensing data signal can be applied to the subpixel SP and a sensing voltage can be provided to the reference line RL through the second transistor T2. Based on this sensing voltage, the data signal for image display can be compensated, and the compensated data signal can be applied to the subpixel SP to compensate the driving transistor Td.

The test transistor Tt for detecting an AC short circuit defect of the subpixel SP is described in detail below.

The test transistor Tt can be configured to be connected between the cathode electrode CE of one subpixel SP among the neighboring subpixels SP and the anode electrode of the other subpixel SP among the neighboring subpixels SP.

Referring to FIG. 2, for example, the test transistor Tt can be connected between the cathode electrode CE of the subpixel SP located on the left side among the two neighboring subpixels SP and the anode electrode (or the node N) of the subpixel SP located on the right side among the two neighboring subpixels SP. In other words, the drain electrode of the test transistor Tt can be connected to the cathode electrode CE of the left subpixel SP, and the source electrode of the test transistor Tt can be connected to the anode electrode of the right subpixel SP.

In addition, the gate electrode of the test transistor Tt can be connected to the test gate line TGL arranged in the corresponding row line.

The test gate signal applied to the test gate line TGL can be applied in, for example, an emission section (or emission period) of the corresponding row line.

Meanwhile, when the test transistor Tt is connected as above, a voltage line VSL can be connected to the cathode electrode CE of the subpixel SP located in the last column line of each row line, for example, the outermost column line on the right. The low potential voltage VSS can be applied to this voltage line VSL. More specifically, the voltage line VSL can be connected to the cathode electrode CE corresponding to the subpixel SP located in the outermost column line on the right (or a portion of the cathode electrode CE located in the non-display region NA on the right of this subpixel SP), and the low potential voltage VSS can be applied to the voltage line VSL during the test process. Meanwhile, after the test process, the voltage line VSL can be in a floating state or can be applied with the low potential voltage VSS.

In the case where the test transistor Tt is arranged as above, as mentioned above, a direction of the current path through the test transistor Tt can be set from the cathode electrode CE connected to one side thereof to the anode electrode connected to the other side thereof.

In order to effectively implement this current path direction, as mentioned above, the cathode electrode CE of the subpixel SP located in the outermost column line on the right, which is the last column line in the current path direction, can be configured to be connected to the voltage line VSL to which the low potential voltage VSS is applied.

In other words, the cathode electrode CE of the subpixel SP in the outermost column line on the right can have a relatively low potential, so that the current path through the test transistors Tt can be formed from the left to the right in the row line.

As such, in the test process, the current path through the test transistor Tt in the row line can be formed from one side to the other side, so that it is possible to effectively detect whether the dark spot defect occurring in the subpixel SP is due to an AC short circuit.

The driving of the test transistor Tt in the test process is described in more detail with further reference to FIG. 3. FIG. 3 is a view illustrating a driving in a test process of a light emitting display device according to an embodiment of the present invention.

Meanwhile, in FIG. 3, for convenience of explanations, an example is given in which the light emitting diode OD of the subpixel SP located in the first left column line among the subpixels SP arranged along the row line has an AC short circuit defect, and the light emitting diodes OD of the remaining subpixels SP are in a normal state.

Referring to FIG. 3, when driving the test transistor Tt in the test process, as mentioned above, the transmission line TL may not be provided with the low potential voltage VSS and can be in a floating state. Accordingly, the cathode electrode CE connected to the transmission line TL, i.e., the cathode electrode CE corresponding to the subpixels SP within the display region AA can be substantially in an electrically floating state.

In addition, as mentioned above, the low potential voltage VSS can be provided to the voltage line VSL connected to the cathode electrode CE of the rightmost subpixel SP of each row line, and accordingly, a state in which the low potential voltage VSS is electrically applied to the cathode electrode CE of the rightmost subpixel SP can be implemented.

In this state, for example, a row line can be scanned, and a gate signal Vg can be applied to the gate line GL and a test gate signal Vtg can be applied to the test gate line TGL. While the gate signal Vg is applied, a data signal DI (or a test data signal) for emission can be applied to the data line DL connected to the subpixel SP of the first column line (i.e., the column line located first in a direction of the current path) on the left side of the row line.

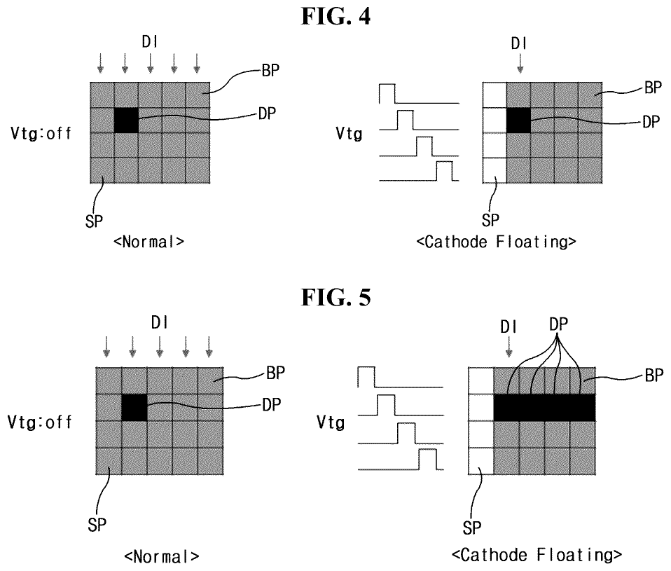

At this time, unlike normal operation, the data signal DI may not be applied to the data lines DL of the remaining column lines except for the first column line and the data lines can be in an off state. However, the present invention is not limited to this, and as described below with respect to FIGS. 4 and 5, a data signal DI may be applied to a data line DL of a specific column line where a subpixel SP being identified as having a dark spot defect during normal driving is located, and an output of a data signal DI can be turned off to the data lines DL of the column lines where the remaining subpixels SP that normally emit light during normal driving are located. During the normal driving, the test transistor Tt is turned off and the light emitting display device 10 is driven normally.

Here, an application section (or scan section or pulse section or turn-on level section) of the test gate signal Vtg can be set to overlap an emission section of the corresponding row line.

For example, the test gate signal Vtg can be generated after the gate signal Vg is applied, so that the application section of the test gate signal Vtg can be set within the emission section of the corresponding row line.

In the above case, the first transistor T1 of the first subpixel SP on the left can be turned on by the gate signal Vg, and the data signal DI transmitted through the data line DL can be supplied to the driving transistor Td. Accordingly, the emission current Id corresponding to the data signal DI can be generated in the emission section and flow to the light emitting diode OD of the first subpixel SP.

Meanwhile, in the emission section, the test transistors Tt arranged in the row line can be turned on by the test gate signal Vtg. Accordingly, a state in which the light emitting diodes OD of the subpixels SP of the row line can be electrically connected in series from the left to the right by the turned-on test transistors Tt can be formed. According to the serial connection state of the light emitting diodes OD, a current path can be implemented in the left to right direction.

At this time, the light emitting diode OD of the first subpixel SP is in an AC short-circuited state, and the emission current Id can pass through the AC short-circuited light emitting diode OD and can be provided to the light emitting diode OD of the second subpixel SP through the turned-on test transistor Tt connected to the AC short-circuited light emitting diode OD. Then, the emission current Id passing through the light emitting diode OD of the second subpixel SP can be provided to the light emitting diode OD of the third subpixel SP through the turned-on test transistor Tt. In this way, the emission current Id can flow from left to right along the current path.

As such, when the emission current Id flows along the current path from the left to the right, the first subpixel SP with the AC short circuit defect is displayed as a dark spot DP because its light emitting diode OD does not emit light, and the remaining subpixels SP can be displayed as bright spots BP because their light emitting diodes OD emit light normally.

Hereinafter, the test process for detecting the dark spot defect caused by the AC short circuit is explained in more detail.

FIG. 4 is a view illustrating a light emitting state in a test process when a dark spot defect due to an AC short circuit exists in a light emitting display device according to an embodiment of the present invention. FIG. 5 is a view illustrating a light emitting state in a test process when a dark spot defect due to a defect other than an AC short circuit exists in a light emitting display device according to an embodiment of the present invention.

In FIGS. 4 and 5, for convenience of explanations, the case where the subpixels SP are arranged in a 4*5 matrix, and a dark spot defect occurs in the subpixel SP at a position (2,2) is illustrated as an example.

Referring to FIGS. 4 and 5 together with FIGS. 1 to 3, in the test process, for example, a process of normally driving the light emitting display device 10 can be performed while applying the low potential voltage VSS to the cathode electrode CE.

During this normal driving process, the test gate signal Vtg is not applied to the test gate line TGL. Accordingly, the test transistor Tt arranged in each row line becomes off, so that the light emitting diodes OD of the subpixels SP in each row line are not electrically connected (i.e., are electrically disconnected), and a current path through them is not formed.

In this normal driving process, the gate line GL can be sequentially scanned, and the gate signal Vg can be applied to each row line, and the data signals DI can be simultaneously output to all data lines DL at the timing of the application of the gate signal Vg. Accordingly, an emission current can be generated in the subpixel SP by the applied data signal DI, and can be applied to the light emitting diode OD.

At this time, the subpixel SP at the position 2,2 that has an AC short circuit defect as shown in FIG. 4 or a defect other than the AC short circuit as shown in FIG. 5 does not emit light due to the defect and is displayed as a dark spot DP.

In addition, the subpixels SP at positions other than the position (2,2) do not have defects and are in a normal state, so that these remaining subpixels SP can emit light normally in response to respective input data signal DI and can be displayed as bright spots BP.

Through the above normal driving process, it can be confirmed that the subpixel SP at the position (2,2) has a dark spot defect.

When the position of the subpixel SP with the dark spot defect is confirmed, in order to check whether the dark spot defect at the position is caused by an AC short circuit, a process of driving the light emitting display device 10 with setting the cathode electrode CE to a floating state can be performed. This driving can be for detecting the cause of the dark spot defect and can be referred to as a cathode floating driving process.

In such cathode floating driving process, the gate line GL can be sequentially scanned and the gate signal Vg can be applied to each row line. In addition, during the scan section of the gate signal Vg of each row line, the data signal DI can be output to the data line DL of the second column line which is the column line of the subpixel SP confirmed as the dark spot DP. At this time, an output of a data signal can be turned off to the data lines DL of the column lines where the remaining subpixels SP that are normally emitting light are located.

In addition, the test gate line TGL can be sequentially scanned, and the test gate signal Vtg can be applied to each row line. The scan section of the test gate signal Vtg can overlap the emission section of the corresponding row line.

As the test gate signal Vtg is applied in this way, the test transistors Tt arranged in the corresponding row line can be turned on, so that the light emitting diodes OD arranged in the row line can be electrically connected in series, and a current path can be formed from the left to the right.

In this state where the current path is formed, when an AC short circuit defect exists in the subpixel SP at the position (2,2) as shown in FIG. 4, the emission current generated according to the data signal DI applied through the corresponding data line DL to this subpixel SP can pass through the AC short-circuited light emitting diode OD and then flow to the normal light emitting diodes OD located on the right along the current path formed in the corresponding row line.

Accordingly, in the second row line where the dark spot DP exists, the subpixel SP of the second column line with the AC short circuit defect does not emit light and is displayed as the dark spot DP, and the subpixels SP of the column lines located on the right emit light normally and can be displayed as the bright spots BP.

Meanwhile, in the remaining row lines where the dark spot DP does not exist, the subpixel SP of the second column line can be displayed as the bright spot BP because the light emitting diode OD emits light normally by an emission current. In addition, this emission current can flow to the light emitting diodes OD of the subpixels SP located on the right along the current path formed in the corresponding row line, so that these light emitting diodes OD can emit light normally and can be displayed as the bright spots BP.

As above, the subpixel SP with the AC short circuit defect is identified as the dark spot DP even when the cathode floating driving is conducted, and other subpixels SP in the same row can be identified as the bright spots BP even when the cathode floating driving is conducted.

Therefore, in the test process, through checking the positions of the dark spot DP and bright spot BP during the normal driving and during the cathode floating driving, if the positions of the dark spot DP and the bright spot BP during the normal driving and during the cathode floating driving are the same, it can be detected that the dark spot DP is caused by the AC short circuit.

Meanwhile, in the case where a defect other than the AC short circuit exists in the subpixel SP at the position (2,2) as shown in FIG. 5, when the cathode floating driving is performed, even if the data signal DI is applied to this subpixel SP, no emission current can be generated, or a generated emission current may not pass through the light emitting diode OD, so that the light emitting diode OD does not emit light and this subpixel SP can be displayed as the dark spot DP.

In this case, in the subpixel SP where the defect exists, an emission current is not output from the cathode electrode CE of the light emitting diode OD to the test transistor Tt, so that the emission current does not flow along the current path formed in the second row line.

Accordingly, in the second row line where the dark spot DP exists, the subpixel SP of the defective second column line does not emit light and is displayed as the dark spot DP, and the subpixels SP of the column lines located on the right can also not emit light and be displayed as the dark spots DP because the emission current is not supplied through the current path.

As above, the subpixel SP with a defect other than the AC short circuit defect can be identified as the dark spot DP even when the cathode floating driving is conducted, and other subpixels SP in the same row line can be identified as the dark spots DP when the cathode floating driving is conducted.

Therefore, in the test process, through checking the positions of the dark spot DP and the bright spot BP during the normal driving and during the cathode floating driving, if the positions of the dark spot DP and the bright spot BP during the normal driving and the cathode floating driving are different, it can be detected that the dark spot DP is caused by a defect other than the AC short circuit.

As described above, in the test process, by checking the positions of the dark spot DP and the bright spot BP during the normal driving and during the cathode floating driving, it is possible to effectively detect whether the dark spot DP displayed during the normal driving are caused by the AC short circuit or not.

Meanwhile, in order to more accurately detect the cause of the dark spot defect, a normal driving can be additionally performed after the cathode floating driving. Through this, the position of the defect during the normal driving can be reconfirmed, and accuracy of the position and cause of the dark spot defect can be further increased. In addition, although FIGS. 4 and 5 only show the case where there is a dark spot at position 2, 2 (i.e., there is one dark spot in one row line), the present invention is not limited thereto. In the case where there are multiple dark spots in one row line, it may be necessary to confirm the cause of each dark spot through the above-mentioned test process multiple times. For example, if two dark spots (e.g., subpixels at positions 2, 2 and 2, 4) are detected in the second row line during normal driving, a data signal may be input to the data line of the second column line similar to the above description to perform a cathode floating driving process. If the positions of the dark spots and the bright spots during normal driving and during cathode floating driving are the same, it can be detected that both dark spots are caused by AC short circuit. If the positions of the dark spots and the bright spots during normal driving and during cathode floating driving are different and the situation shown on the right side of FIG. 5 occurs, it can be determined that the dark spot of the subpixel at position 2, 2 is caused by a defect other than AC short circuit. For the subpixel at position 2, 4, another test process is required. In this test process, for example, a data signal may be input only to the data line of the fourth column line to perform the cathode floating driving to confirm the cause of the dark spot at the position 2, 4. As an alternative, data signals may be input to the data lines of the second column line and the fourth column line at the same time, and then the causes of the dark spots may be determined according to the positions of the dark spots during the cathode floating driving.

Hereinafter, an example of a structure of the light emitting display device that implements the detection of the dark spot defect as described above is described.

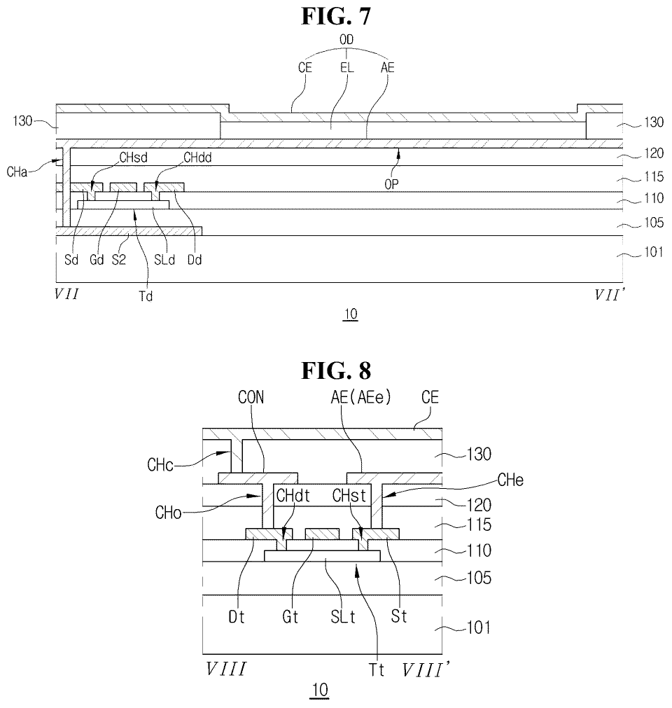

FIG. 6 is a plan view schematically illustrating a subpixel of a light emitting display device according to an embodiment of the present invention. FIG. 7 is a cross-sectional view taken along a line VII-VII′ of FIG. 6, illustrating a cross-sectional structure of a light emitting diode and a driving transistor of a subpixel. FIG. 8 is a cross-sectional view taken along a line VIII-VIII′ of FIG. 6, illustrating a cross-sectional structure of a test transistor.

Meanwhile, for convenience of explanations, FIG. 6 illustrates the subpixels SP on both sides connected to the power line PL disposed therebetween by way of example.

Referring to FIGS. 1 to 5 and FIGS. 6 to 8, on a substrate 101 of the light emitting display device 10 of this embodiment, the first and second transistors T1 and T2 and the driving transistor Td in a driving circuit region of the subpixel SP and the light emitting diode OD positioned on the transistors T1, T2, and Td and configured in an emission region can be formed. In addition, the test transistor Tt electrically connected between the cathode electrode CE of one of the neighboring subpixels SP and the anode electrode AE of the other of the neighboring subpixels SP can be formed.

The test transistor Tt can be formed in the corresponding subpixel SP, and for example, a source electrode St of the test transistor Tt can be connected to the anode electrode AE of the corresponding subpixel SP, and a drain electrode Dt of the test transistor Tt can be connected to the cathode electrode CE. By this connection structure of the test transistor Tt, as shown in FIGS. 2 and 3, the test transistor Tt disposed in the subpixel SP can have a configuration in which it is electrically connected to the cathode electrode CE of the adjacent left subpixel SP.

Meanwhile, the light emitting diode OD can be configured in a top emission type or a bottom emission type. For example, in the case of the top emission type, light can pass through the cathode electrode CE and be output upward, and in the case of the bottom emission type, light can pass through the anode electrode AE and be output downward.

The substrate 101 can use, for example, a glass substrate or a plastic substrate having insulating properties. As another example, the substrate 101 can use a silicon wafer. In this embodiment, for convenience of explanations, the case where the substrate 101 is formed of an glass substrate or a plastic substrate is taken as an example.

The first transistor T1 can include a source electrode (or first source electrode) S1, a drain electrode (or first drain electrode) D1, a gate electrode (or first gate electrode) G1, and a semiconductor layer (or first semiconductor layer) SL1.

The second transistor T2 can include a source electrode (or second source electrode) S2, a drain electrode (or second drain electrode) D2, a gate electrode (or second gate electrode) G2, and a semiconductor layer (or second semiconductor layer) SL2.

The driving transistor Td can include a source electrode (or third source electrode) Sd, a drain electrode (or third drain electrode) Dd, a gate electrode (or third gate electrode) Gd, and a semiconductor layer (or third semiconductor layer) SLd.

The test transistor Tt can include a source electrode (or fourth source electrode) St, a drain electrode (or fourth drain electrode) Dt, a gate electrode (or fourth gate electrode) Gt, and a semiconductor layer (or fourth semiconductor layer) SLt.

For example, regarding the stacked structure of the transistors T1, T2, Td, and Tt, the drain electrode D1 of the first transistor T1 and the source electrode S2 of the second transistor T2 can be formed on the substrate 101, and a buffer layer 105 formed of an insulating material can be formed on the electrodes D1 and S2. Meanwhile, the data line DL can be formed at the same layer as the electrodes D1 and S2. In addition, a second line PL2, which is part of the power line PL, can be formed at the same layer as the electrodes D1 and S2.

The buffer layer 105 can be formed of, for example, an inorganic insulating material such as silicon oxide (SiO2) or silicon nitride (SiNx), but not limited thereto.

On the buffer layer 105, the semiconductor layers SL1, SL2, SLd, and SLt of the first and second transistors T1 and T2, the driving transistor Td, and the test transistor Tt can be formed. Each of the semiconductor layers SL1, SL2, SLd, and SLt can include a channel region in the middle and source and drain regions on both sides thereof.

The semiconductor layers SL1, SL2, SLd, and SLt can be formed of, for example, polycrystalline silicon, amorphous silicon, or an oxide semiconductor.

A gate insulating layer 110 can be formed on the semiconductor layers SL1, SL2, SLd, and SLt. The gate insulating layer 110 can be formed of an inorganic insulating material such as silicon oxide (SiO₂) or silicon nitride (SiNx), but not limited thereto.

On the gate insulating layer 110, the gate electrodes G1, G2, Gd, and Gt of the first and second transistors T1 and T2, the driving transistor Td, and the test transistor Tt can be formed. In addition, the source electrode S1 of the first transistor T1, the drain electrode D2 of the second transistor T2, the source electrode Sd and the drain electrode Dd of the driving transistor Td, and the source electrode St and the drain electrode Dt of the test transistor Tt can be formed at the same layer as the gate electrodes G1, G2, Gd, and Gt. Meanwhile, the gate line GL and the test gate line TGL can be formed at the same layer as the gate electrodes G1, G2, Gd, and Gt. In addition, the reference line RL, and a first line PL1 which is part of the power line PL can be formed at the same layer as the gate electrodes G1, G2, Gd, and Gt.

The source electrode S1 of the first transistor T1 and the gate electrode Gd of the driving transistor Td can be formed integrally.

The power line PL can include the first line PL1 and the second line PL2 that are connected to each other, and the second line PL2 can be formed to cross the gate line GL and the test gate line TGL. The second line PL2 can be, for example, in contact with the first lines PL1 thereon through contact holes CHp to be connected to the first lines PL1, and the contact hole CHp can be formed in the buffer layer 105 and the gate insulating layer 110.

In addition, the drain electrode D1 of the first transistor T1 can be, for example, in contact with the drain region of the corresponding semiconductor layer SL1 through a contact hole CHd1 formed in the buffer layer 105.

The source electrode S2 of the second transistor T2 can be, for example, in contact with the source region of the corresponding semiconductor layer SL2 through a contact hole CHs2 formed in the buffer layer 105. The drain electrode D2 of the second transistor T2 can be, for example, in contact with the drain region of the corresponding semiconductor layer SL2 through a contact hole CHd2 formed in the gate insulating layer 110.

The source electrode S1 of the first transistor T1 can be, for example, in contact with the source region of the corresponding semiconductor layer SL1 through a contact hole CHs1 formed in the gate insulating layer 110. The source electrode Sd and the drain electrode Dd of the driving transistor Td can be, for example, in contact with the source region and the drain region of the corresponding semiconductor layer SLd through respective contact holes CHsd and CHdd formed in the gate insulating layer 110.

The source electrode St and the drain electrode Dt of the test transistor Tt can be, for example, in contact with the source region and the drain region of the corresponding semiconductor layer SLt through respective contact holes CHst and CHdt formed in the gate insulating layer 110, respectively.

At least one insulating layer can be formed on the transistors T1, T2, Td, and Tt configured as described above. In this embodiment, the case where the passivation layer 115 and the planarization layer 120 can be formed on the transistors T1, T2, Td, and Tt is taken as an example.

The passivation layer 115 can be formed of, for example, an inorganic insulating material such as silicon oxide (SiO₂) or silicon nitride (SiNx), or an organic insulating material such as photo acrylic or benzocyclobutene. The planarization layer 120 can be formed of, for example, an inorganic insulating material such as silicon oxide (SiO₂) or silicon nitride (SiNx), or an organic insulating material such as photo acrylic or benzocyclobutene.

On the planarization layer 120, the anode electrode AE can be formed for each subpixel SP. For example, when the light emitting display device 10 is a bottom emission type, the anode electrode AE can include a transparent conductive layer formed of a transparent conductive material such as ITO or IZO. When the light emitting display device 10 is a top emission type, the anode electrode AE can include a reflective layer formed of a metal with high reflective characteristics such as Ag.

The anode electrode AE can be, for example, in contact with the source electrode Sd of the driving transistor Td through a contact hole CHa formed in the planarization layer 120 and the passivation layer 115. Moreover, the contact hole CHa can penetrate the source electrode Sd of the driving transistor Td and be formed in the gate insulating layer 110 and the buffer layer 105, and through the contact hole CHa formed in this way, the anode electrode AE can contact the source electrode Sd of the driving transistor Td and the source electrode S2 of the second transistor T2.

Meanwhile, the anode electrode AE can include an extension portion AEe that extends to the test transistor Tt and is connected to the source electrode St of the test transistor Tt.

For example, the extension portion AEe of the anode electrode AE can extend over the source electrode St of the test transistor Tt and contact the source electrode St of the test transistor Tt through a contact hole CHe formed in the planarization layer 120 and the passivation layer 115.

Meanwhile, for example, an island-shaped connection electrode CON located at the same layer as the anode electrode AE can be formed on the drain electrode Dt of the test transistor Tt. The connection electrode CON can be formed separately and physically spaced from the anode electrode AE. The connection electrode CON can be, for example, in contact with the drain electrode Dt of the test transistor Tt through a contact hole CHo formed in the planarization layer 120 and the passivation layer 115.

Meanwhile, on the planarization layer 120 and the anode electrode AE, a bank 130 can be formed along a boundary of each subpixel SP. The bank 130 can include an opening OP that exposes the anode electrode AE, and the bank 130 can cover an edge of the anode electrode AE. The opening OP of the bank 130 can define the emission region of the subpixel SP. In this case, a region, where the bank 130 is formed, in the subpixel SP can be considered as a non-emission region.

A light emitting layer EL can be formed on the anode electrode AE. The light emitting layer EL can include a light emitting material (e.g., organic light emitting material) that produces a color light of its subpixel SP or emits white light.

A cathode electrode CE can be formed on the light emitting layer EL. For example, the cathode electrode CE can be formed in a continuous form across the entire display region AA to correspond to all subpixels SP.

When the light emitting display device 10 is a bottom emission type, the cathode electrode CE can include, for example, a reflective layer formed of a metal with high reflective characteristics, such as Ag. When the light emitting display device 10 is a top emission type, the cathode electrode CE can include, for example, a transparent conductive layer formed of a transparent conductive material, such as ITO or IZO.

As above, in each subpixel SP, the light emitting diode OD configured with the anode electrode AE, the light emitting layer EL, and the cathode electrode CE can be formed in the emission region.

Meanwhile, a portion of the cathode electrode CE located in the region where the test transistor Tt is formed can be connected to the drain electrode Dt of the test transistor Tt. For example, the cathode electrode CE can contact the connection electrode CON through a contact hole CHc formed in the bank 130. Accordingly, the cathode electrode CE can be connected to the drain electrode Dt of the test transistor Tt via the connection electrode CON.

By the connection structure of the test transistor Tt as described above, the test transistor Tt can electrically connect the anode electrode AE of the subpixel SP and the cathode electrode CE of the adjacent left subpixel SP, thereby forming a current path between the adjacent light emitting diodes OD in the test process.

As described above, according to the embodiment of the present invention, the test transistor can be formed between the cathode electrode of the subpixel on one side among the neighboring subpixels in the row line and the anode electrode the subpixel on the other side among the neighboring subpixels in the row line, and the test transistor can be driven in the test process to electrically connect the light emitting diodes in series from one side to the other side in the row line, thereby forming the current path through which the emission current can flow.

Accordingly, in the test process, by checking and comparing the dark spot and the bright spot during the normal driving with the dark spot and the bright spot during the driving of the test transistor, it is possible to effectively detect whether or not the dark spot defect is caused by the AC short circuit, thereby improving the detection rate of the dark spot defect due to the AC short circuit. As such, by improving the detection rate of the dark spot defect due to the AC short circuit, an appropriate improvement method to address a dark spot defect issue can be devised.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A light emitting display device, comprising:
a substrate including a display region in which subpixels are arranged along row lines and column lines;
a light emitting diode in each of the subpixels, and including an anode electrode, a light emitting layer on the anode electrode, and a cathode electrode on the light emitting layer;
a test transistor in a row line among the row lines, and including a source electrode connected to the anode electrode of a subpixel among neighboring subpixels in the row line and a drain electrode connected to the cathode electrode of another subpixel among the neighboring subpixels in the row line; and
a test gate line connected to a gate electrode of the test transistor,
wherein when the test transistor is turned on and a current path is formed in the row line, the cathode electrode of the another subpixel among the neighboring subpixels in the row line is in an electrically floating state.

2. The light emitting display device of claim 1, wherein when the test transistor is turned off and the light emitting display device is driven normally, a low potential voltage is applied to the cathode electrode of the another subpixel among the neighboring subpixels in the row line.

3. The light emitting display device of claim 1, wherein when the test transistor is turned on and the current path is formed in the row line, a low potential voltage is applied to the cathode electrode of the subpixel located last in a direction of the current path.

4. The light emitting display device of claim 3, wherein the cathode electrode of the subpixel located last in the direction of the current path is connected to a voltage line supplied with the low potential voltage.

5. The light emitting display device of claim 1, wherein the anode electrode of the subpixel among the neighboring subpixels in the row line includes an extension portion that extends over the source electrode of the test transistor, and is connected to the source electrode of the test transistor.

6. The light emitting display device of claim 5, wherein the extension portion contacts the source electrode of the test transistor through a first contact hole formed in an insulating layer below the extension portion.

7. The light emitting display device of claim 6, wherein the cathode electrode of the another subpixel among the neighboring subpixels in the row line is formed corresponding to the display region, and
wherein a bank is configured to cover an edge of the anode electrode of the subpixel among the neighboring subpixels in the row line.

8. The light emitting display device of claim 7, wherein a connection electrode formed at a same layer as the anode electrode of the subpixel among the neighboring subpixels in the row line contacts the drain electrode of the test transistor through a second contact hole formed in the insulating layer, and
wherein the cathode electrode of the another subpixel among the neighboring subpixels in the row line contacts the connection electrode through a third contact hole formed in the bank.

9. The light emitting display device of claim 7, further comprising a transmission line surrounding the display region and connected to the cathode electrode of the another subpixel among the neighboring subpixels in the row line,
wherein when a voltage output from a power circuit to the transmission line is turned off, the cathode electrode of the another subpixel among the neighboring subpixels in the row line is in the electrically floating state.

10. The light emitting display device of claim 1, wherein a scan section of a test gate signal applied to the test gate line is set to overlap an emission section of the row line, wherein the emission section is a period in which an emission current corresponding to an applied data signal is provided to the light emitting diode.

11. The light emitting display device of claim 10, wherein during the scan section of the test gate signal,
a data signal is applied to a data line of a first column line located first in a direction of the current path, and an output of a data signal is turned off to data lines of remaining column lines except for the first column line, or
a data signal is applied to a data line of a column line where a subpixel being identified as having a dark spot defect during normal driving is located, and an output of a data signal is turned off to data lines of column lines where remaining subpixels that normally emit light during the normal driving are located,
wherein during the normal driving, the test transistor is turned off and the light emitting display device is driven normally.

12. A light emitting display device, comprising:
a substrate including a display region in which subpixels are arranged along row lines and column lines;
a light emitting diode in each of the subpixels; and
a test transistor in a row line among the row lines, and connected between an anode electrode of the light emitting diode of a first subpixel among neighboring subpixels in the row line and a cathode electrode of the light emitting diode of a second subpixel among the neighboring subpixels in the row line,
wherein when the test transistor is turned on and the light emitting diodes of the row line are electrically connected in series, the cathode electrode of the light emitting diode of the second subpixel is in an electrically floating state.

13. The light emitting display device of claim 12, wherein when the test transistor is turned off and the light emitting display device is driven normally, a low potential voltage is applied to the cathode electrode of the light emitting diode of the second subpixel.

14. The light emitting display device of claim 12, wherein when the test transistor is turned on and the light emitting diodes of the row line are electrically connected in series, a low potential voltage is applied to the cathode electrode of the subpixel located last in a direction of a current path of the connection in series.

15. The light emitting display device of claim 12, wherein the anode electrode of the light emitting diode of the first subpixel includes an extension portion that extends over a source electrode of the test transistor and is connected to the source electrode of the test transistor.

16. The light emitting display device of claim 15, wherein the extension portion contacts the source electrode of the test transistor through a first contact hole formed in an insulating layer below the extension portion.

17. The light emitting display device of claim 16, wherein the cathode electrode of the light emitting diode of the second subpixel is formed corresponding to the display region, and
wherein a bank is configured to cover an edge of the anode electrode of the light emitting diode of the first subpixel.

18. The light emitting display device of claim 17, wherein a connection electrode formed at a same layer as the anode electrode of the light emitting diode of the first subpixel contacts a drain electrode of the test transistor through a second contact hole formed in the insulating layer, and
wherein the cathode electrode of the light emitting diode of the second subpixel contacts the connection electrode through a third contact hole formed in the bank.

19. The light emitting display device of claim 12, wherein the light emitting diode is one of a top emission type or a bottom emission type.
